(19) United States
(12) Patent Application Publication
(10) Pub. No.: US 2020/0140987 A1
(43) Pub. Date: May 7, 2020

(54) Direct write plasma spraying technology applied to the semiconductor industry

(71) Applicant: SHENYANGFORTUNEPRECISIONEQUIPMENT CO.,LTD, Shenyang, Liaoning (CN)

(72) Inventors: Junyang Xu, Shenyang, Liaoning (CN); Jia Lee, Shenyang, Liaoning (CN); Ying Shao, Shenyang, Liaoning (CN)

(21) Appl. No.: 16/631,216

(22) PCT Filed: Oct. 16, 2018
(86) PCT No.: PCT/CN2018/110325

§ 371 Date: Jan. 15, 2020

(30) Foreign Application Priority Data
Jun. 13, 2018 (CN) 201810604257.6

(51) Int. Cl. C23C 4/134; C23C 4/01; C23C 4/11; H01L 21/02; H01L 35/34; H01L 43/12; H01L 43/08; G01N 27/04; G01R 27/02

(52) U.S. Cl. CPC C23C 4/134; C23C 4/01; C23C 4/11; H01L 21/02266; H01L 35/34; G01R 27/02; H01L 21/02178; H01L 21/02175; H01L 43/08; G01N 27/048; H01L 43/12

(57) ABSTRACT

A direct-write plasma spray technique for semiconductor industry. For coated parts in semiconductors, the sensor is written on the coating by direct-write plasma spraying technology, and the change in coating quality is monitored by sensor to achieve replacing coating of the parts before the coating reaches the end of service life. The method includes, (1) coating a functional coating according to needs of semiconductor component; (2) spraying a small area of other coating over coating, wherein the coating needs to be at a certain performance and first the functional coating of layer is clearly distinguishable; the coating cannot be coated with sensitive metal coating in the semiconductor industry; (3) above the second coating, spraying coating of the same material as the first coating; wherein a thickness is slightly smaller than the first layer of coating; (4) spraying radio over the coating to connect external monitoring equipment.

### CROSS REFERENCE OF RELATED APPLICATION

This is a U.S. National Stage under 35 U.S.C 371 of the International Application PCT/CN2018/110325, filed Oct. 16, 2018, which claims priority under 35 U.S.C. 119(a-d) to CN 201810604257.6, filed Jun. 13, 2018.

### BACKGROUND OF THE PRESENT INVENTION

### Field of Invention

The present invention relates to a direct-write plasma spraying method for a semiconductor industry.

### Description of Related Arts

With the rapid development of the semiconductor industry, the reduction of the size of semiconductor devices, and the increase in the size of silicon wafers, plasma etching technology has become more and more widely applied in the preparation of semiconductor devices. The etching gas for plasma etching is commonly adopts gases such as CF₄, SF₆, NF₃, and Cl₂. During the dry etching process of the plasma, these etching gases etch the semiconductor components and also have corrosive effects on key components such as aluminum and aluminum alloy. At present, in the semiconductor industry, in order to prevent the parts from being corroded, a layer of Al₂O₃ or Y₂O₃, etc. is usually coated outside the parts, but the coating has a certain service life. When the coating reaches the end of the service life, the coating needs to be replaced. Not only does it cause frequent replacement and maintenance of critical components, but if the parts cannot be replaced in time, the silicon wafer will be affected in serious cases, and even lead to failure of the etching process chamber and damage of the device.

With the development of plasma spraying technology, people just want to continuously improve the corrosion resistance or wear resistance of key components in the etching chamber, and develop coatings with stronger corrosion resistance and wear resistance. However, the corrosion-resistant coating, no matter how hard, has a certain life. When the corrosion-resistant coating reaches the end of the service life, if not found timely, other components will be affected and unpredictable damage will be caused.

Conventional plasma spraying only sprays materials with different functionalities over a large area, so that the coating has a certain effect. However, in many devices, especially the structural modes of the metal interior and the resistor are required to be device level performance. These structural patterns are either formed by comprehensive addition and removal or by integrated additive manufacturing. The former is a method that is easy to establish in the electronics industry, while the latter is called “direct writing”. Direct writing means that computer-aided function are added when creating material patterns, and direct writing methods include many novel electronic and sensor applications. Direct-write plasma spraying is a new type of manufacturing technology that utilizes direct deposition of multiple layers of electronic film by depositing different electronic coating materials on the substrate. Direct-input plasma spray technology can spray different electronic/sensor coatings on different substrate materials and ensure geometry. The direct-write plasma spray technology is suitable for applications requiring a substrate temperature of less than 200° C. and no other post-processing equipment. Directly written plasma sprays naturally create multi-layer devices with different material coatings, especially for electronics and sensor applications.

In this paper, the direct-injection plasma spraying technology is used to spray the “sensor” onto the coating of the part. The sensor can be used to monitor the corrosion or wear of the parts in the etching chamber, and “alarm” and stop work before the part is damaged, so that not only can observe the working conditions of the components, but also affections on other core components such as wafers are avoided.

### SUMMARY OF THE PRESENT INVENTION

A technical problem to be solved by the present invention is to utilize a direct-write plasma spray to manufacture a sensor to monitor a coating life of a semiconductor component, and to issue an alarm prompt before the coating life reaches the limit, so that relevant personnel is capable of replacing the component in advance to prevent the life of other components from being affected by coating damage.

Accordingly, in order to achieve the objects mentioned above, a technical solution adopted by the present invention is as follows.

A direct-write plasma spraying method for a semiconductor device, comprises steps of:

(1) spraying coatings with different materials or thickness by plasma spraying on different substrates;

(2) usually spraying two or more different coatings on an identical substrate by the direct-write plasma spraying method;

(3) constructing a functional miniature device comprising a sensor, and a thermocouple on the identical substrate, according to a performance characteristic of each of the coatings; and

(4) spraying embedded radio in a middle of the coatings or over a top coating to connect an external related equipment to observe changes in the miniature device.

Preferably, the spraying method is atmospheric plasma spraying technology, supersonic flame plasma spraying or suspension plasma spraying technology.

Preferably, the coatings in the step (1) have performances of wear resistance, corrosion resistance, high temperature oxidation, electrical insulation and leak-tightness.

Preferably, the functional miniature device in the steps (2) and (3) is a sensor having a thermistor function by adopting different resistances of different coating layers; a magnetic sensor by adopting different magnetic properties of different coatings; micro-thermoelectrics by adopting different thermal conductivity of different coating layers; or sensors and electronic devices with other functions.

Preferably, the radio in the step (4) applied in the semiconductor industry is laser-sprayed to embed the radio into the coatings.

A direct-write plasma spray method for a semiconductor industry, which is characterized in that the direct-write plasma spray method is applied in the semiconductor industry and in silicon rings and nozzles of an etching machine to manufacture sensors.

Preferably, the direct-write plasma spray method for the semiconductor industry, comprises manufacturing a resistive sensor by direct-write plasma spraying on a silicon ring, comprising: using an atmospheric plasma spraying Al₂O₃ coating on a silicon ring with a coating thickness of 75 μm; and then spraying a semiconductor coating of NiAl on a small area of 1-2 cm² on the Al₂O₃ coating, wherein a thickness of the semiconductor coating is 10 μm; and then spraying Al₂O₃ coating on the semiconductor coating with an area slightly larger than the semiconductor coating, wherein a coating thickness of the Al₂O₃ coating on the semiconductor coating is slightly smaller than Al₂O₃ coating sprayed on a first layer, about 70 μm; coating laser-sprayed radio on a third layer of Al₂O₃ coating to connect an external observation equipment; by a different resistance of Al₂O₃ coating and NiAl coating to form a resistance sensor.

The direct-write plasma spray method for the semiconductor industry is applied in manufacturing a humidity sensor on a nozzle, comprising: spraying a Y₂O₃ coating on the nozzle, wherein a thickness of the Y₂O₃ coating is 25 μm; and then spraying a semiconductor coating of NiCr on a small area on the Y₂O₃ coating, wherein a thickness of the semiconductor coating is 5 μm; and then spraying Y₂O₃ coating on the semiconductor coating of NiCr with an area slightly larger than the semiconductor coating, wherein a coating thickness of the Y₂O₃ coating on the semiconductor coating is slightly smaller than Y₂O₃ coating sprayed on a first layer, about 20 μm; coating micro-laser-sprayed radio on a third layer of Y₂O₃ coating to connect an external observation equipment; by an adhering layer of NiCr and different resistance of NiCr coating and Y₂O₃ coating to form a resistance sensor.

The beneficial effects of the invention are as follows.

(1) The change of the coating of the components can be monitored to replace the coating of the components before the coating life is reached;

(2) Different types of sensors can be manufactured taking advantage of different material performance characteristics

(3) The present invention has high production and manufacturing efficiency, low production cost, and unlimited production environment.

### BRIEF DESCRIPTION OF THE DRAWINGS

FIG. 1 is a schematic diagram of a sensor prepared by a direct-write plasma spray method.

FIG. 2 is a schematic diagram of a resistive sensor built on a silicon ring.

FIG. 3 is a diagram showing resistance variation of a coating on the silicon ring.

FIG. 4 is a schematic diagram of a humidity sensor built on a nozzle.

FIG. 5 is a diagram showing the change in the humidity of the coating on the nozzle.

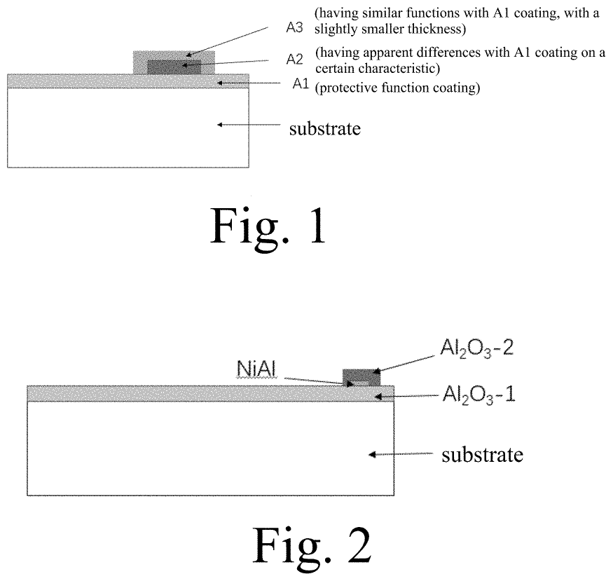

### DETAILED DESCRIPTION OF THE PREFERRED EMBODIMENT

The technical solutions of the present invention are described in detail below with reference to the accompanying drawings and examples.

A sensor for directly applying of plasma spray technology to the semiconductor industry has characteristics as follows.

Taking aluminum alloy parts in semiconductors as an example, in order to protect the parts from corrosion by etching gas, it is usually plated on the surface.

The corrosion-resistant coating is the first layer, as shown in FIG. A1.

Spray a layer of conductive coating on a part of the part that does not affect the assembly, but not a metal coating, spray area is 1 cm², which is the second layer, as shown in A2 in the drawing.

The same coating as the first layer is sprayed on the basis of the second layer, but the thickness is thinner than the thickness of the coating of the first layer, which is the third layer, as shown by A3 in the drawing.

A radio is sprayed on the third layer for connection to an external observing system.

The sensor works by: the sensor consists of three layers of coating, the first layer and the third layer are the same coating as Al₂O₃, Y₂O₃ coating or other coating, which is an insulating layer, and the second layer can be made of a semiconductor layer. (or have different properties from the first layer in some respects), have certain electrical conductivity (or other significantly different properties), and utilize the difference in resistance (or other different properties) of the second and third layers The external monitor monitors changes in the coating by monitoring changes in resistance. Since the first layer and the third layer are the same coating, the corrosion rate of the coating is uniform. When the part is just loaded into the semiconductor device, the first and third layers of the corrosion-resistant coating provide protection. The external monitor monitors that the resistance value of the coating is low. As the corrosion time of the part increases, the resistance value will become larger. When the coating of the third layer is penetrated by the corrosive gas, the resistance will reach a peak. Since the coating thickness of the third layer is thinner than the coating thickness of the first layer, the coating of the first layer is still protecting the parts, and the parts should be replaced at this time. In this way, not only the coating itself but also other important components (such as wafers) are affected before the first coating is penetrated by the corrosive gas. First, it is possible to observe the change of the coating at any time; second, it is possible to replace the parts in advance and protect the parts.

### Embodiment 1

In the present invention, a silicon ring in a semiconductor etching machine is taken as an example. In order to prevent the etching gas from being applied to the silicon ring, an Al₂O₃ coating is usually sprayed on the outside of the silicon ring. As shown in FIG. 2, the present invention provides a method for preparing a sensor by using a direct-write plasma spraying technique on a semiconductor silicon ring to monitor a coating change of a silicon ring, and specifically includes the following steps:

(1) Al₂O₃ coating is sprayed on the silicon ring by atmospheric plasma spraying, and is labeled Al₂O₃-1 for differentiation. The spraying process parameters are: the spraying power is set to 35 KW, the powder injection angle is 90°, the main gas is argon gas, the gas flow rate is 0.8 L/s, the auxiliary gas is hydrogen gas, the gas flow rate is 0.083 L/s, and the spraying distance is 130 mm. Spray rate is 500/s, coating thickness is approximately 75 microns.

(2) spraying a layer of semiconductor coating NiAl with an area of about 1-2 cm² outside the Y₂O₃ coating. The spraying process parameters are: spraying power is 20 KW, powder injection angle is 90°, main gas is argon, gas flow is 50 L/min, spray distance is 120 mm, coating thickness is 10 microns.

(3) spraying the Al₂O₃ coating again on the NiAl coating by atmospheric plasma spraying. For the classification, mark Al₂O₃-2. The spraying process is the same as that of the first layer of Al₂O₃ coating. The coating thickness is 70 microns.

(4) The embedded radio is sprayed on the outermost Al₂O₃ coating by spraying and laser micro-nozzles to connect external monitoring equipment.

FIG. 2 shows a schematic diagram of a resistance sensor fabricated directly by plasma spraying. The Al₂O₃ coating is an insulator with a large electrical resistance. The NiAl coating is a semiconductor. The resistance is smaller than the Al₂O₃ coating. The sensor uses the difference in coating resistance to observe the coating change. When the silicon ring works normally in the etching machine, the outer ring of the silicon ring is Al₂O₃ coating, which plays a role of anti-corrosion. At this time, the resistance value monitored is the resistance value of the Al₂O₃-2 coating, and the resistance value is large. As the working time of the silicon ring increases, the corrosion resistance of the Al₂O₃-2 coating gradually decreases when working for a certain period of time. At this time, the lifetime of the Al₂O₃-2 coating and the Al₂O₃-1 coating are consistent. When the corrosive gas corrodes the coating and the radio contacts the NiAl coating, the resistance value decreases rapidly. At this time, the detected resistance value is at the lowest value, which proves that the life of the Al₂O₃-2 coating has reached the limit due to the Al₂O₃-1 coating. The thickness of the layer is slightly thicker than that of the Al₂O₃-2 coating, indicating that the lifetime of the Al₂O₃-1 coating is close to the limit, but it also has a certain corrosion resistance, ensuring that the silicon ring is not exposed in the etching chamber. At this point, the observed resistance

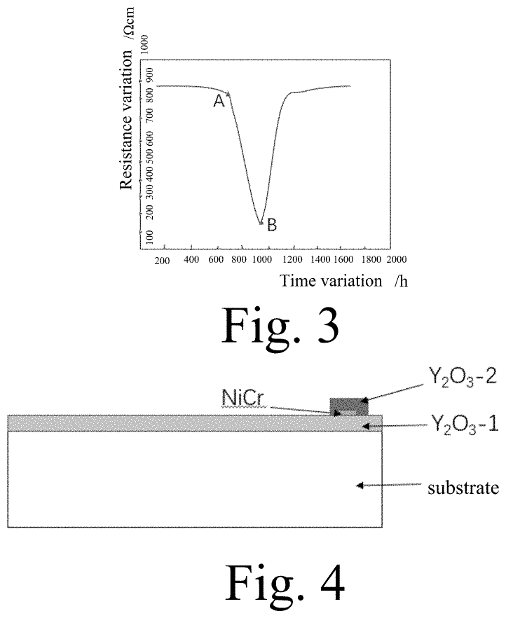

The change is shown in FIG. 3. When the resistance reaches point A, it means that the Al₂O₃-2 coating is approaching the life limit, but it is still protecting. When the resistance reaches the lowest peak (ie point B), it is the “alarm” notice that represents the Al₂O₃-2 coating. It has been penetrated by corrosive gases, proving that the silicon ring should be removed and the Al₂O₃ coating re-sprayed. The staff can determine whether to remove the coating at point A or point B according to their own understanding of the equipment. The change in resistance observed by the resistance sensor is indicative of the change in the Al₂O₃-1 coating. Since the Al₂O₃-1 coating and the Al₂O₃-2 coating are made of the same material and the same spraying process, they can be coated with Al₂O₃-2. The lifetime of the layer reflects the coating life of Al₂O₃-1. Therefore, the resistance sensor can monitor the change in the lifetime of the Al₂O₃-1 coating on the surface of the silicon ring.

### Embodiment 2

Taking the nozzle in the semiconductor etching machine as an example, the probability of the nozzle being corroded by the etching gas is more serious than that of the silicon ring, and the Y₂O₃ coating is usually sprayed to prevent corrosion. As shown in FIG. 3, the present invention provides a method for preparing a humidity sensor by using a direct-write plasma spraying technique on a semiconductor nozzle to monitor a coating change of the nozzle, and specifically includes the following steps:

(1) spraying Y₂O₃ coating on the silicon ring by atmospheric plasma spraying. The spraying process parameters are: spraying power is set to 30 KW, powder injection angle is 90°, main gas is argon gas, gas flow rate is 40 L/min, auxiliary gas is hydrogen, a gas flow rate of 15 L/min, a spray distance of 220 mm, and a coating thickness of approximately 25 microns;

(2) spraying a layer of semiconductor coating NiCr with an area of about 1-2 cm² outside the Y₂O₃ coating to a thickness of 5 μm;

(3) spraying the Y₂O₃ coating again on the NiCr coating by atmospheric plasma spraying at a coating thickness of 20 microns; and

(4) applying an embedded radio to the outermost Y₂O₃ coating by spraying and laser micro-nozzles to connect external monitoring equipment.

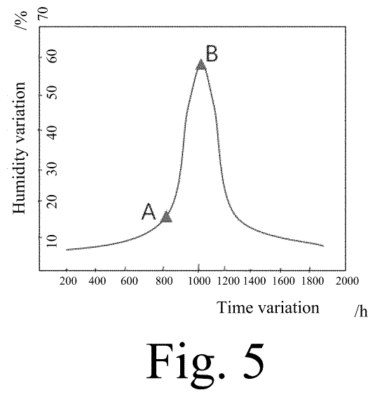

FIG. 4 shows a humidity sensor prepared by direct-write plasma spraying. The Y₂O₃ coating has good corrosion resistance, while the NiCr has poor corrosion resistance and uses a difference in corrosion resistance to construct the humidity sensor. When the nozzle is working normally in the etching machine, the Y₂O₃ coating acts as an anti-corrosion. At this time, the humidity induced by the radio is very low; as the working time increases, when working for a certain time, Y₂O₃-2 is coated. The corrosion resistance of the layer is gradually weakened. At this time, the lifetime of the Y2O3-2 coating and the Y₂O₃-1 coating are consistent. When the corrosive gas penetrates the Y₂O₃-2 coating, the radio can sense the H⁺ and H3O⁺ ions due to the weak corrosion resistance of the NiCr coating, at which point the humidity increases and peaks. It indicates that the Y₂O₃-2 coating life has reached the limit, and because the Y₂O₃-2 coating is slightly thinner than the Y₂O₃-1 coating, it indicates that the life of the Y₂O₃-1 coating is close to the limit, but it can also play a certain role. Corrosion resistance ensures that the nozzle is not exposed to the etch chamber. During this process, the observed changes in humidity are shown in FIG. 5. When the humidity reaches point A, it means that the Y₂O₃-2 coating is approaching the life limit, but it is still anti-corrosive; when the humidity reaches point B, it means that the Y₂O₃-2 coating has reached the life limit. The nozzle should be removed and the Y₂O₃ coating re-sprayed. The staff can determine whether to remove the nozzle at point A or point B to change the coating based on his or her knowledge of the condition of the equipment.

The change in humidity observed by the humidity sensor can represent a change in the Y₂O₃-1 coating because the humidity change observed by the humidity sensor first represents the change in the Y₂O₃-2 coating due to the Y₂O₃-2 coating and the Y₂O₃-1 coating. The coatings made of the same material and the same process have the same coating properties, so they can represent the variation of the Y₂O₃-1 coating. Therefore, the change in coating life of the Y₂O₃-1 coating can be monitored by the humidity sensor.

The above is only the preferred embodiment of the present invention, and is not intended to limit the present invention, and various modifications and changes can be made to the present invention. The invention can be used for various coated parts in the semiconductor industry, and the sensor constructed by the invention is not only a resistor or a humidity sensor, and the invention is not limited to constructing a sensor by using a three-layer coating, which can be applied according to practical applications. In view of the circumstances, the spraying technique used in the present invention is not limited to atmospheric plasma spraying, and other spraying techniques such as supersonic plasma spraying may be applied; the coating applied by the present invention is not limited to the embodiment. Any modifications, equivalent substitutions, improvements, etc. made within the spirit and scope of the present invention is intended to be included within the scope of the present invention.

What is claimed is:

1. A direct-write plasma spraying method for a semiconductor device, comprising steps of:
(1) spraying coatings with different materials or thickness by plasma spraying on different substrates;
(2) usually spraying two or more different coatings on an identical substrate by the direct-write plasma spraying method;
(3) constructing a functional miniature device comprising a sensor, and a thermocouple on the identical substrate, according to a performance characteristic of each of the coatings; and
(4) spraying embedded radio in a middle of the coatings or over a top coating to connect an external related equipment to observe changes in the miniature device.

2. The direct-write plasma spraying method for a semiconductor device, as recited in claim 1, wherein the spraying method is atmospheric plasma spraying technology, supersonic flame plasma spraying or suspension plasma spraying technology.

3. The direct-write plasma spraying method for a semiconductor device, as recited in claim 1, wherein the coatings in the step (1) have performances of wear resistance, corrosion resistance, high temperature oxidation, electrical insulation and leak-tightness.

4. The direct-write plasma spraying method for a semiconductor device, as recited in claim 1, wherein the functional miniature device in the steps (2) and (3) is a sensor having a thermistor function by adopting different resistances of different coating layers; a magnetic sensor by adopting different magnetic properties of different coatings; micro-thermoelectrics by adopting different thermal conductivity of different coating layers; or sensors and electronic devices with other functions.

5. The direct-write plasma spraying method for a semiconductor device, as recited in claim 1, wherein the radio in the step (4) applied in the semiconductor industry is laser-sprayed to embed the radio into the coatings.

6. A direct-write plasma spray method for a semiconductor industry, which is characterized in that the direct-write plasma spray method is applied in the semiconductor industry and in silicon rings and nozzles of an etching machine to manufacture sensors.

7. The direct-write plasma spray method for the semiconductor industry, as recited in claim 6, comprising manufacturing a resistive sensor by direct-write plasma spraying on a silicon ring, comprising: using an atmospheric plasma spraying Al₂O₃ coating on a silicon ring with a coating thickness of 75 μm; and then spraying a semiconductor coating of NiAl on a small area of 1-2 cm² on the Al₂O₃ coating, wherein a thickness of the semiconductor coating is 10 μm; and then spraying Al₂O₃ coating on the semiconductor coating with an area slightly larger than the semiconductor coating, wherein a coating thickness of the Al₂O₃ coating on the semiconductor coating is slightly smaller than Al₂O₃ coating sprayed on a first layer, about 70 μm; coating laser-sprayed radio on a third layer of Al₂O₃ coating to connect an external observation equipment; by a different resistance of Al₂O₃ coating and NiAl coating to form a resistance sensor.

8. The direct-write plasma spray method for the semiconductor industry, as recited in claim 6, being applied in manufacturing a humidity sensor on a nozzle, comprising: spraying a Y₂O₃ coating on the nozzle, wherein a thickness of the Y₂O₃ coating is 25 μm; and then spraying a semiconductor coating of NiCr on a small area on the Y₂O₃ coating, wherein a thickness of the semiconductor coating is 5 μm; and then spraying Y₂O₃ coating on the semiconductor coating of NiCr with an area slightly larger than the semiconductor coating of NiCr, wherein a coating thickness of the Y₂O₃ coating on the semiconductor coating is slightly smaller than Y₂O₃ coating sprayed on a first layer, about 20 μm; coating micro-laser-sprayed radio on a third layer of Y₂O₃ coating to connect an external observation equipment; by an adhering layer of NiCr and different resistance of NiCr coating and Y₂O₃ coating to form a resistance sensor.
